(19) United States
(12) Patent Application Publication
(10) Pub. No.: US 2026/0311637 A1
(43) Pub. Date: Oct. 8, 2026

(54) DISPLAY MODULE, METHOD OF MANUFACTURING DISPLAY MODULE, DISPLAY APPARATUS, COMPENSATION METHOD, AND ELECTRONIC DEVICE

(71) Applicants: Chengdu BOE Optoelectronics Technology Co., Ltd., Sichuan (CN); BOE Technology Group Co., Ltd., Beijing (CN)

(72) Inventors: Xue Meng, Beijing (CN); Rongkun Fan, Beijing (CN); Jialin Wang, Beijing (CN); Qiang Pu, Beijing (CN); Fei Zeng, Beijing (CN); Wei Zhou, Beijing (CN); Yongsong Meng, Beijing (CN); Guodong Zhou, Beijing (CN); Haitao Liang, Beijing (CN); Yu Zhao, Beijing (CN); Xu Zhang, Beijing (CN)

(73) Assignees: Chengdu BOE Optoelectronics Technology Co., Ltd., Sichuan (CN); BOE Technology Group Co., Ltd., Beijing (CN)

(21) Appl. No.: 19/480,702

(22) PCT Filed: Jan. 7, 2025
(86) PCT No.: PCT/CN2025/071048

§ 371 Date: Oct. 31, 2025

(30) Foreign Application Priority Data
Jan. 30, 2024 (CN) 202410130449.3

(51) Int. Cl. G09G 3/3208; G09G 3/32

(52) U.S. Cl. CPC G09G 3/3208; G09G 3/32; G09G 2300/0871; G09G 2310/08; G09G 2320/0233; G09G 2320/0276; G09G 2320/0626; G09G 2330/021

(57) ABSTRACT

A display module, a method of manufacturing a display module, a display apparatus, a compensation method and an electronic device are provided. The display module includes: a display panel (100), a first PCB (110), a second PCB (120) and a transfer circuit (130). The first PCB (110) is bound to the display panel (100), and the first PCB (110) is provided with a transfer interface (113). The second PCB (120) is provided with a timing control chip (121) and a first memory chip (122). The transfer circuit (130) includes a first connection terminal and a second connection terminal, the first connection terminal is electrically connected to a signal output terminal of the second PCB (120), and the second connection terminal is plugged and connected to the transfer interface (113), so as to transmit a signal output by the second PCB (120) to the first PCB (110).

### CROSS REFERENCE TO RELATED APPLICATION(S)

This application claims the benefit of priority to Chinese Patent Application No. 202410130449.3, filed on Jan. 30, 2024, the entire content of which is incorporated herein by reference in its entirety.

### TECHNICAL FIELD

The present disclosure belongs to a field of display technology, and relates to a display module, a method of manufacturing a display module, a display apparatus, a compensation method, and an electronic device.

### BACKGROUND

In recent years, a self-luminous display panel has been developed rapidly and widely used in various display products due to its advantages of fast response, wide viewing angle, high brightness, bright color, lightness, etc. However, due to loss of production process or use, the self-luminous display panel is prone to a Mura phenomenon of a display screen. Therefore, a Demura technology for eliminating the Mura phenomenon has emerged as the times require. The Demura technology is a technology for detecting the Mura phenomenon in a display panel and eliminating the Mura phenomenon, thereby achieving uniform brightness of the display screen.

### SUMMARY

In a first aspect of the present disclosure, a display module is provided, including: a display panel; a first PCB bound to the display panel, where the first PCB is provided with a transfer interface; a second PCB provided with a timing control chip and a first memory chip, where the timing control chip is electrically connected to the first memory chip; and a transfer circuit including a first connection terminal and a second connection terminal, where the first connection terminal is electrically connected to a signal output terminal of the second PCB, and the second connection terminal is plugged and connected to the transfer interface, so as to transmit a signal output by the second PCB to the first PCB.

According to the first aspect of the present disclosure, in some embodiments, the first PCB is further provided with a second memory chip configured to store verification data, the verification data is used to verify to-be-burned brightness compensation data, if verification of the brightness compensation data is successful, the brightness compensation data is burned into the first memory chip.

According to the first aspect of the present disclosure, in some embodiments, the second PCB is further provided with a power management integrated circuit, a level shift circuit and a gamma circuit, the power management integrated circuit and the level shift circuit are electrically connected to the timing control chip, and the gamma circuit is electrically connected to the power management integrated circuit.

In a second aspect of the present disclosure, a method of manufacturing the display module provided in the first aspect of the present disclosure is provided, including: binding the display panel to the first PCB; performing a Demura process on the display panel in advance to generate brightness compensation data for the display panel, and storing the brightness compensation data and identification information of the display panel in association in a target position; forming a cover plate on the display panel; plugging the second PCB into the first PCB; and downloading the brightness compensation data from the target position based on the identification information of the display panel, and burning the downloaded brightness compensation data into the first memory chip provided on the second PCB.

According to the second aspect of the present disclosure, in some embodiments, the first PCB is provided with the second memory chip, and after generating the brightness compensation data for the display panel, the method further includes: generating verification data of the brightness compensation data, and writing the verification data into the second memory chip. The storing the brightness compensation data and identification information of the display panel in association in a target position includes: storing the brightness compensation data, the verification data of the brightness compensation data and the identification information of the display panel in association in the target position. Before burning the downloaded brightness compensation data into the first memory chip provided on the second PCB, the method further includes: reading the verification data from the second memory chip, comparing the read verification data with verification data of the downloaded brightness compensation data, and in response to the read verification data being consistent with the verification data of the downloaded brightness compensation data, burning the downloaded brightness compensation data into the first memory chip provided on the second PCB.

According to the second aspect of the present disclosure, in some embodiments, after forming the cover plate on the display panel and before plugging the second PCB into the first PCB, the method further includes: performing a light-on test on the display panel. Before storing the brightness compensation data and the identification information of the display panel in association in the target position, the method further includes: obtaining a simulation diagram for the light-on test based on the brightness compensation data. The storing the brightness compensation data and identification information of the display panel in association in a target position includes: storing the brightness compensation data, the simulation diagram and the identification information of the display panel in association in the target position.

According to the second aspect of the present disclosure, in some embodiments, the performing a light-on test on the display panel includes: acquiring the identification information of the display panel; downloading the simulation diagram from the target position based on the identification information; and controlling the display panel to display the simulation diagram, so as to perform the light-on test.

According to the first aspect of the present disclosure, in some embodiments, the first PCB is provided with the second memory chip, and after generating the brightness compensation data for the display panel, the method further includes: generating verification data of the brightness compensation data, and writing the verification data into the second memory chip. The storing the brightness compensation data, the simulation diagram and the identification information of the display panel in association in the target position includes: storing the brightness compensation data, the verification data of the brightness compensation data, the simulation diagram and the identification information of the display panel in association in the target position. The downloading the simulation diagram from the target position based on the identification information of the display panel, and controlling the display panel to display the simulation diagram includes: downloading the simulation diagram and the verification data from the target position based on the identification information of the display panel, reading the verification data from the second memory chip, comparing the read verification data with the downloaded verification data, and in response to the read verification data being consistent with the downloaded verification data, controlling the display panel to display the simulation diagram.

In a third aspect of the present disclosure, a display apparatus is provided, including: the display module provided in the first aspect of the present disclosure.

In a fourth aspect of the present disclosure, a brightness compensation method for the display module provided in the first aspect of the present disclosure is provided, including: acquiring brightness compensation data and identification information of a to-be-compensated display panel, and storing the brightness compensation data and the identification information in association in a target position; and acquiring identification information of a to-be-burned display panel, downloading the brightness compensation data from the target position based on the acquired identification information, and burning the downloaded brightness compensation data into the first memory chip provided on the second PCB.

According to the fourth aspect of the present disclosure, in some embodiments, the first PCB of the display module is provided with the second memory chip, and the storing the brightness compensation data and the identification information in association in a target position includes: generating verification data of the brightness compensation data; writing the verification data into the second memory chip; and storing the brightness compensation data, the verification data of the brightness compensation data and the identification information in association in the target position.

According to the fourth aspect of the present disclosure, in some embodiments, the downloading the brightness compensation data from the target position based on the acquired identification information, and burning the downloaded brightness compensation data into the first memory chip provided on the second PCB includes: downloading the brightness compensation data and the verification data of the brightness compensation data from the target position based on the acquired identification information; reading the verification data from the second memory chip; and comparing the read verification data with the downloaded verification data, and in response to the read verification data being consistent with the downloaded verification data, burning the downloaded brightness compensation data into the first memory chip provided on the second PCB.

According to the fourth aspect of the present disclosure, in some embodiments, the storing the brightness compensation data, the verification data of the brightness compensation data and the identification information in association in the target position includes: obtaining a simulation diagram for a light-on test based on the brightness compensation data; and storing the brightness compensation data, the simulation diagram and the identification information in association in the target position.

According to the fourth aspect of the present disclosure, in some embodiments, the above-mentioned brightness compensation method further includes: acquiring identification information of a to-be-tested display panel, downloading the simulation diagram from the target position based on the acquired identification information, and controlling the to-be-tested display panel to display the downloaded simulation diagram, so as to perform the light-on test.

In a fifth aspect of the present disclosure, an electronic device is provided, including: a memory, a processor, and a computer program stored in the memory and executable on the processor, where the computer program, when executed by the processor, is configured to implement steps of the brightness compensation method provided in the fourth aspect of the present disclosure.

The above-mentioned description is only a summary of the technical solutions provided by some embodiments of the present disclosure. In order to clearly understand the technical means of embodiments of the present disclosure, the technical means may be implemented in accordance with the content of the specification. In order to make embodiments of the present disclosure more clear and understandable, the detailed descriptions of embodiments of the present disclosure will be given below.

### BRIEF DESCRIPTION OF THE ACCOMPANYING DRAWINGS

In order to clearly describe the technical solutions in the content of the present disclosure, the accompanying drawings required for the description of the embodiments will be briefly introduced below. Clearly, the accompanying drawings in the following descriptions are for some of the embodiments of the present disclosure. For those skilled in the art, other accompanying drawings may also be obtained according to these accompanying drawings without any creative work.

FIG. 1 shows a schematic structural diagram of an exemplary display module;

FIG. 2 shows a schematic diagram of a display module according to some embodiments of the present disclosure;

FIG. 3 shows a schematic diagram of a first PCB according to some embodiments of the present disclosure;

FIG. 4 shows a schematic diagram of a second PCB according to some embodiments of the present disclosure;

FIG. 5 shows a schematic structural diagram of a display apparatus according to some embodiments of the present disclosure;

FIG. 6 shows a flowchart of a method of manufacturing a display module according to some embodiments of the present disclosure;

FIG. 7 shows a flowchart of a method of manufacturing a display module according to other embodiments of the present disclosure;

FIG. 8 shows a Demura effect diagram of an exemplary curved screen; and

FIG. 9 shows a flowchart of a brightness compensation method according to some embodiments of the present disclosure.

### DETAILED DESCRIPTION OF EMBODIMENTS

Exemplary embodiments of the present disclosure will be described in more detail below with reference to the accompanying drawings. Although the accompanying drawings show exemplary embodiments of the present disclosure, it should be understood that the present disclosure may be implemented in various forms and should not be limited by the embodiments set forth herein. On the contrary, these embodiments are provided to enable a more thorough understanding of the present disclosure and to fully convey the scope of the present disclosure to those skilled in the art.

It should be noted that a term “plurality” as used herein means two or more. “At least one” means one or more. A word “include”, “comprise”, or “contain” means that an element or item preceding the word covers elements or items listed after the word and their equivalents, but does not exclude other elements or items. Terms such as “upper”, “lower”, “left” and “right” are only used to indicate relative positional relationships. When an absolute position of the described object changes, the relative positional relationship may also change accordingly.

Terms “parallel”, “perpendicular” and “equal” as used herein include the stated situations and situations similar to the stated situations, and the scope of the similar situations is within an acceptable deviation range. The acceptable deviation range is determined by those skilled in the art in consideration of the measurement in question and errors related to measurement of particular quantities (i.e., the limitation of a measurement system). For example, the “parallel” includes absolute parallelism and approximate parallelism, where an acceptable deviation range for the approximate parallelism may be, for example, a deviation within 5°; the “perpendicular” includes absolute perpendicularity and approximate perpendicularity, where an acceptable deviation range for the approximate perpendicularity may also be, for example, a deviation within 5°; the “equal” includes absolute equality and approximate equality, where an acceptable deviation range for the approximate equality may be, for example, that a difference between the two equal items is less than or equal to 5% of either item.

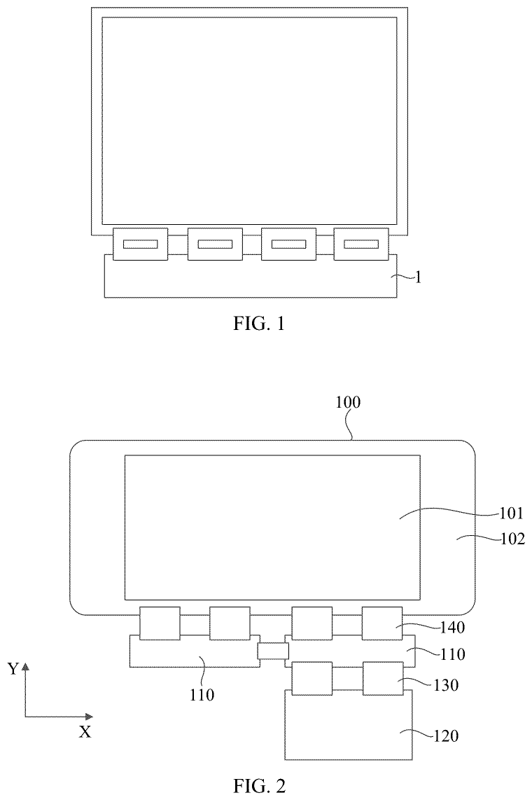

FIG. 1 shows a schematic structural diagram of an exemplary display module. As shown in FIG. 1, in an existing medium-sized display module, all integrated circuit chips (ICs) and peripheral devices are usually integrated on a single PCB 1. After a module folding-back process, the PCB 1 generates severe heat on the back of a display screen, which may not meet some customers' needs. Moreover, if a module has binding loss or physical damage, the entire PCB 1 may be scrapped, resulting in a high cost and a long electronic material cycle.

Furthermore, in order to meet customers' customized needs, the form of a display product, such as an in-vehicle display product, is becoming increasingly diverse. A conventional manufacturing process of a display module involves performing a Demura process on the module after completing a cover plate bonding process. In the actual production research, the inventors found that there are some difficulties in the implementation of the Demura process: (1) there is an inability to focus on the entire screen: a thickness of a cover plate is large, and an existing photographing mechanism (one camera, one-time imaging) may not be applied to a product with a large depth; (2) a device needs to be modified frequently: for display products of different forms, a technology such as camera stitching (i.e., camera multi-step shooting) or line-scan camera needs to be used, but it is difficult to implement the technology in mass production at present, and the device mechanism is complex, with a high precision requirement, a large layout, and high difficulty in a preprocessing algorithm; (3) an outer layer of the cover plate is usually provided with various functional film layers, such as an anti-fingerprint (AF) film layer, an anti-reflection (AR) film layer, an anti-glare (AG) film layer, etc. These film layers often affect the photographing of a Demura device, failing to accurately capture real brightness of each pixel, and even leading to incorrect Demura compensation.

Therefore, some embodiments of the present disclosure further provide a display module and a display apparatus, which are provided with two types of PCBs, i.e., a first printed circuit board PCB and a second printed circuit board PCB. High-cost chips such as a timing control chip, a first memory chip, etc. are provided on the second PCB, so that the second PCB may be assembled by plugging after the manufacturing process of the display module is substantially completed, which is beneficial to reducing waste of electronic materials caused by a module binding process loss or physical damage and saving a production cost.

Furthermore, some embodiments of the present disclosure further provide a method of manufacturing a display module, a brightness compensation method, and an electronic device. The Demura process may be implemented before forming the cover plate, and the above-mentioned difficulties caused by the cover plate in the implementation of the Demura process may be effectively avoided, which is conducive to reducing a difficulty of implementing the Demura process and ensuring a Demura effect.

The display module, the method of manufacturing the display module, the display apparatus, the compensation method, and the electronic device provided by some embodiments of the present disclosure will be described in detail below with reference to the accompanying drawings.

FIG. 2 shows a schematic diagram of a display module according to some embodiments of the present disclosure. As shown in FIG. 2, some embodiments of the present disclosure provide a display module 10, including: a display panel 100, a first PCB 110, a second PCB 120, and a transfer circuit 130. The first PCB 110 is bound to the display panel 100, and the first PCB 110 is provided with a transfer interface 113. The second PCB 120 is provided with a timing control chip 121 and a first memory chip 122, and the timing control chip 121 is electrically connected to the first memory chip 122. The transfer circuit 130 includes a first connection terminal and a second connection terminal. The first connection terminal is electrically connected to a signal output terminal of the second PCB 120, and the second connection terminal is plugged and connected to the transfer interface 113 on the first PCB 110, so as to transmit a signal output by the second PCB 120 to the first PCB 110.

Since important devices such as the timing control chip 121, the first memory chip 122, etc. are separately provided on the second PCB 120, and the second PCB 120 is plugged into the first PCB 110 through the transfer circuit 130, the second PCB 120 may be assembled after the manufacturing process of the display module is substantially completed, so as to reduce waste of electronic materials caused by a module binding process loss or physical damage and save a production cost. Imagine that if an entire PCB provided with important IC devices such as the timing control chip 121, etc. is directly bound to the display panel 100, not only a binding process loss may be easily caused, but also a yield loss may easily occur in an intermediate process of the module, for example, the timing control chip 121 is at risk of physical damage, chip falling, etc.

As shown in FIG. 2, the display panel 100 may include a display region 101 and a non-display region 102 disposed on at least one side of the display region 101. The display region 101 includes a plurality of pixels arranged in an array. In some embodiments, each pixel may include a plurality of sub-pixels, and each sub-pixel may display a single color. For example, a red sub-pixel displays red, a green sub-pixel displays green, and a blue sub-pixel displays blue. Brightness (gray scale) of sub-pixels of different colors in each pixel may be adjusted, and various colors may be displayed through color combination and superposition, thereby achieving color display of the display panel 100. In some embodiments, the above-mentioned plurality of sub-pixels include three sub-pixels, i.e., a first sub-pixel, a second sub-pixel, and a third sub-pixel, and emission colors of different sub-pixels are different. For example, the first sub-pixel may be a red sub-pixel, the second sub-pixel may be a green sub-pixel, and the third sub-pixel may be a blue sub-pixel. In other embodiments, each pixel may also include other numbers of sub-pixels, such as four sub-pixels, which may be set based on actual application scenarios, and the present disclosure is not limited thereto. In other embodiments, each pixel may also include only one sub-pixel, and the sub-pixel has a plurality of light-emitting layers with different light-emitting colors arranged in a stack, so as to achieve color display by controlling a light-emitting sequence of each light-emitting layer, and the present disclosure is not limited thereto.

The non-display region 102 on at least one side of the display region 101 is provided with a binding region, and the binding region includes a plurality of binding pads. In some embodiments, the first PCB 110 may be bound to the display panel 100 through a Chip On Flex (COF) 140. One end of the COF 140 is bound to the above-mentioned plurality of binding pads, and the other end of the COF 140 is bound to the first PCB 110.

In some embodiments, the display panel 100 may be a self-luminous display panel, such as an Organic Light Emitting Diode (OLED) display panel or a Quantum Dot Light Emitting Diode (QLED) display panel. The specific type may be set based on needs of actual application scenarios, and the present disclosure is not limited thereto.

In some embodiments, the first PCB 110 may extend in an X-axis direction in FIG. 2, and therefore may also be called an XPCB. The number of the first PCBs 110 may be one or more, which is set based on actual product needs, and the present disclosure is not limited thereto. In FIG. 2, two first PCBs 110 are taken as an example for illustration. In some embodiments, a plurality of first PCBs 110 may be provided. The plurality of first PCBs 110 may be electrically connected through a flexible circuit board. The second PCB 120 is plugged into at least one of the first PCBs 110 through the transfer circuit 130.

The second PCB 120 is provided with important IC devices such as the timing control chip 121 (Timing Controller IC, referred to as TCON IC), the first memory chip 122, etc., and therefore may also be called a TCON board. In some embodiments, the first memory chip 122 may be a non-volatile memory, such as a flash chip. In addition to the timing control chip 121 and the first memory chip 122, the second PCB 120 may also be provided with other relatively important devices based on actual product needs, and the present disclosure is not limited thereto.

In some embodiments, the transfer circuit 130 may be implemented by a flexible printed circuit (FPC). The second PCB 120 is plugged into the first PCB 110 through a transfer FPC provided with the transfer circuit 130, so that signals output by the second PCB 120, such as data signals, gate driving signals (e.g., GOA signals), etc., are respectively transmitted to a source driving circuit and a gate driving circuit of the display panel 100 through the first PCB 110. In some embodiments, the second PCB 120 may also be provided with a transfer interface. By plugging a first connection terminal of the transfer FPC into the transfer interface on the second PCB 120 and a second connection terminal of the transfer FPC into the transfer interface 113 on the first PCB 110, the plugging and connecting between the second PCB 120 and the first PCB 110 may be achieved, thereby completing the assembly of the second PCB 120.

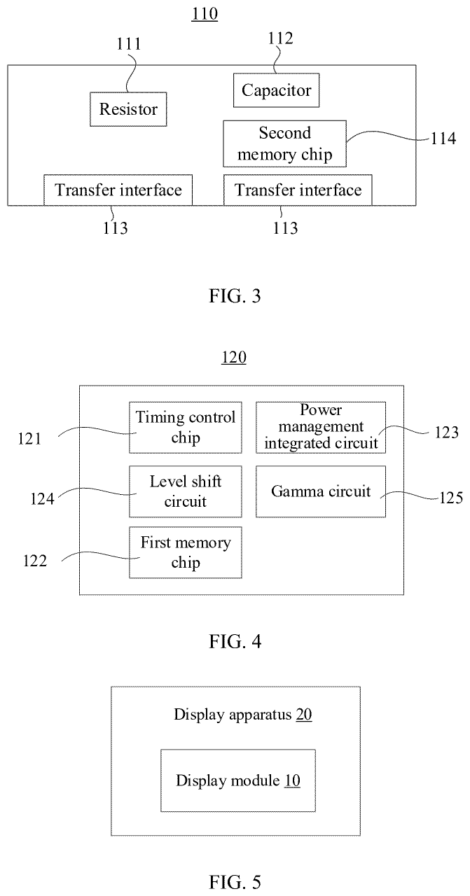

FIG. 3 shows a schematic diagram of the first PCB 110 according to some embodiments of the present disclosure, and FIG. 4 shows a schematic diagram of the second PCB 120 according to some embodiments of the present disclosure. As shown in FIG. 3, the first PCB 110 may be provided with conventional devices such as a capacitor 112, a resistor 111, etc., and the transfer interface 113. As shown in FIG. 4, the second PCB 120 is provided with the timing control chip 121, the first memory chip 122, a power management integrated circuit (PMIC) 123, a level shift (LS) circuit 124, and a Gamma circuit 125. The power management integrated circuit 123 and the level shift circuit 124 are electrically connected to the timing control chip 121, and the Gamma circuit 125 is electrically connected to the power management integrated circuit 123. The Gamma circuit 125 may be implemented by, for example, a programmable gamma correction buffer circuit chip (P_Gamma IC). It should be noted that the positions of the devices shown in FIG. 3 and FIG. 4 on the respective PCBs are only schematic and may not be construed as a limitation. The actual positions are determined based on circuit layout needs. In addition to the devices shown in FIG. 3 and FIG. 4, the first PCB 110 and the second PCB 120 may also be provided with other devices based on actual product needs. For example, the second PCB 120 may also be provided with a display interface, and the present disclosure is not limited thereto.

As shown in FIG. 3, in some embodiments, the first PCB 110 is further provided with a second memory chip 114 used to store verification data, and the verification data is used to verify to-be-burned brightness compensation data, and if verification of the brightness compensation data is successful, the brightness compensation data is burned into the first memory chip 122, so as to ensure that the wrong data is not burned into the screen. In some embodiments, the second memory chip 114 may be an electrically erasable programmable read-only memory (EEPROM).

FIG. 5 shows a schematic structural diagram of a display apparatus 20 according to some embodiments of the present disclosure. As shown in FIG. 5, some embodiments of the present disclosure provide a display apparatus 20, including the display module 10 provided in any one of the above-mentioned embodiments. The display apparatus 20 may be a flat display product or a curved-screen display product. The display apparatus 20 may include, for example, an in-vehicle display screen, a wearable display product, a monitor, a television, a tablet computer, a notebook computer, a mobile phone, a digital photo frame, a navigator, and other products or components with display functions. The display apparatus 20 provided by embodiments of the present disclosure is not limited to the types listed above.

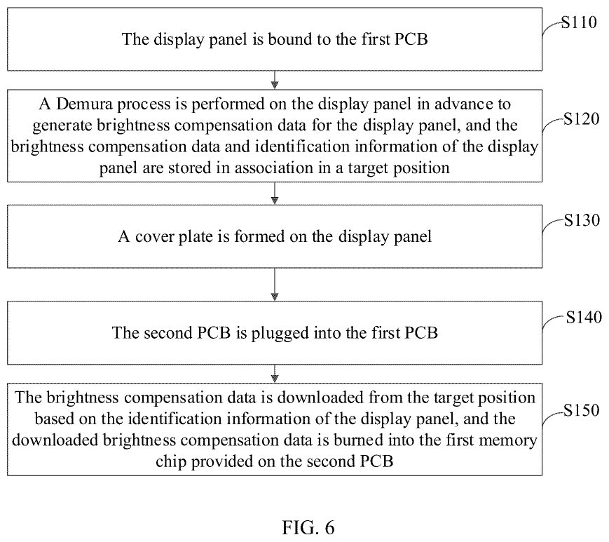

FIG. 6 shows a flowchart of a method of manufacturing the display module 10 according to some embodiments of the present disclosure. Some embodiments of the present disclosure provide a method of manufacturing the display module 10 in any one of the above-mentioned embodiments. As shown in FIG. 6, the manufacturing method may include at least the following steps S110 to S150.

In the step S110, the display panel is bound to the first PCB.

In the step S120, a Demura process is performed on the display panel in advance to generate brightness compensation data for the display panel, and the brightness compensation data and identification information of the display panel are stored in association in a target position.

In the step S130, a cover plate is formed on the display panel.

In the step S140, the second PCB is plugged into the first PCB.

In the step S150, the brightness compensation data is downloaded from the target position based on the identification information of the display panel, and the downloaded brightness compensation data is burned into the first memory chip provided on the second PCB.

In the manufacturing process of the display module 10, after the display panel 100 (without the cover plate attached) is manufactured, the above-mentioned step S110 may be executed to bind the first PCB 110 to the display panel 100. After completing the binding of the first PCB 110, the above-mentioned step S120 is executed to perform the Demura process on the display panel 100 in advance, and then the step S130 is executed.

After binding the first PCB 110 and before forming the cover plate on the display panel 100, the Demura process is performed on the display panel 100, and the obtained brightness compensation data and the identification information of the display panel 100 are stored in association in the target position. After the second PCB 120 is assembled, the brightness compensation data is downloaded from the target position based on the identification information of the display panel 100 and burned into the first memory chip 122 provided on the second PCB 120, so as to eliminate Mura of the display panel 100. By performing Demura of the display panel 100 before forming the cover plate, on the basis of substantially not affecting time consumption of an entire module process, design problems brought by the cover plate to the Demura process are effectively avoided and incorrect Demura compensation caused by a functional film layer coated on an outer layer of the cover plate is prevented, which is conducive to reducing a difficulty of implementing the Demura process and ensuring a Demura effect.

A mass production line of the display module 10 is provided with a plurality of stations, such as a Demura station, a cover plate bonding station, a light-on test station, an assembly station for the second PCB 120, etc. It should be noted that the above-mentioned division of stations is only schematic. These stations may all be different stations, or some of them may be the same station, which may be set based on actual production line needs, and the present disclosure is not limited thereto.

In some embodiments, the Demura station may collect the identification information (Panel ID) of the display panel 100 through an identification collection device, which may store the brightness compensation data and the identification information in association in the target position after generating the brightness compensation data, thereby distinguishing the brightness compensation data of different display panels 100. It should be noted that the identification collection device is adapted to the identification setting method of the display panel 100. For example, if an identification is set by attaching or printing a graphic code on the display panel 100, the identification collection device may be a code scanner, such as a camera, so as to collect the identification information of the display panel 100 in real time by scanning the code.

An industrial control system used in the mass production line of the display module 10 is provided with a host computer for issuing a control command. One or more host computers may be provided. For example, each station may be provided with a host computer. The host computer may be, for example, a personal computer (PC) or other suitable computer devices. In some embodiments, each host computer may access a communication system used in a module production line through a network, so as to achieve the upload and download of data.

In some embodiments, a host computer of the Demura station may upload pre-generated brightness compensation data to the target position for storage, so that the brightness compensation data may be downloaded from the target position when burning is required later. In some embodiments, the brightness compensation data may be a binary (bin) file, or other applicable file types, and the present disclosure is not limited thereto. In some embodiments, the target position may be a local database, a cloud, etc., which may be set based on actual needs, and the present disclosure is not limited thereto.

In some embodiments, data may be written into the PCB of the display panel 100 using a programmer (PG). The programmer, also referred to as as a burner, is connected to the host computer and a universal fixture of the display panel 100. It should be noted that since the method of manufacturing the display module 10 provided by some embodiments of the present disclosure involves assembling the second PCB 120 after the manufacturing process of the display module 10 is substantially completed, in order to control the display panel 100 to display an image so as to meet test requirements in an intermediate process of the display module 10, a pre-configured universal fixture may be plugged into the first PCB 110 to temporarily replace a function of the second PCB 120.

In some embodiments, the brightness compensation data for the display panel 100 includes a brightness compensation value for each pixel, and each pixel may include at least one sub-pixel. In the above-mentioned step S120, the process of performing the Demura process on the display panel 100 in advance to generate the brightness compensation data for the display panel 100 may include: controlling the display panel 100 to display a preset image; collecting an image of a display screen through a camera; acquiring a brightness value of each pixel in the collected image; and determining a compensation brightness value of each pixel based on a difference between a target brightness value and the brightness value of each pixel in the image, so that the brightness compensation data for the display panel 100 may be acquired. For specific details, reference may be made to the related art, and no further description will be provided herein. It may be understood that, by acquiring the brightness value of each pixel in the collected image and analyzing the brightness value, abnormal brightness regions of the display screen, i.e., regions where a Mura phenomenon occurs, may be determined. In the actual use, the brightness of the above-mentioned abnormal brightness region may be adjusted using the obtained brightness compensation data, making overly dark regions brighter and overly bright regions darker, thereby eliminating the above-mentioned Mura phenomenon of the display panel 100 and achieving a display effect with uniform brightness.

In the step S130, a cover plate may be formed on the display panel 100 by means of bonding. The cover plate may be, for example, a cover glass (CG), or other cover plate materials may also be used. A shape of the cover plate is adapted to a shape of the display panel 100. The cover plate may be a flat cover plate or a curved cover plate, which is determined based on actual display product needs. For example, for a curved display product, bonding of the flexible display panel 100 and the curved cover plate may be achieved by a 3D bonding device.

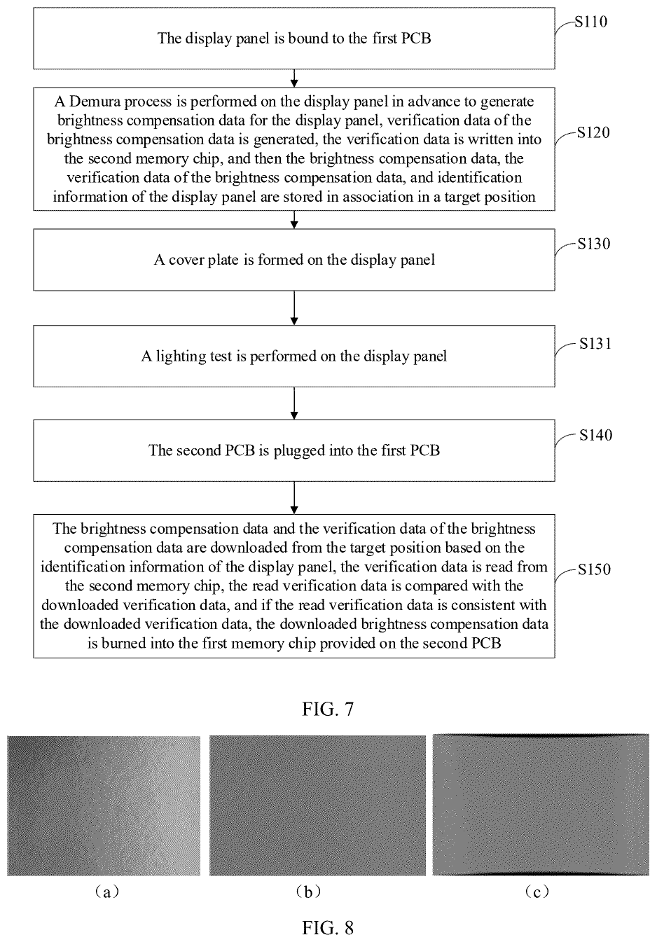

FIG. 7 shows a flowchart of a method of manufacturing the display module 10 according to other embodiments of the present disclosure. As shown in FIG. 7, after executing the step S130 and before executing the step S140, the above-mentioned manufacturing method further includes: step S131 of performing a light-on test on the display panel. That is, it is necessary to control the display panel 100 to display an image, so as to detect image conditions, such as brightness uniformity, a presence of defective pixels or not, etc.

In order to improve an efficiency of the light-on test, in some embodiments, in after generating the brightness compensation data and before storing the brightness compensation data and the identification information of the display panel 100 in association in the target position in the above-mentioned step S120, the above-mentioned manufacturing method further includes: obtaining a simulation diagram for the light-on test based on the brightness compensation data. For example, a plurality of test gray scales may be determined in advance, and an image compensated by the brightness compensation data under these test gray scales may be generated as a simulation diagram for an inspection image required for a subsequent light-on test. For specific details, reference may be made to the related art, and no further description will be provided herein.

Based on this, in some embodiments, the process of storing the brightness compensation data and the identification information of the display panel 100 in association in the target position in the above-mentioned step S120 may include: storing the brightness compensation data, the simulation diagram and the identification information of the display panel in association in the target position. In some embodiments, the brightness compensation data and simulation diagram applicable to the display panel 100 may be stored in association by using the identification information of the display panel 100 as an index in the target position, which may facilitate downloading required data from the target position in a subsequent module process, thereby improving a data acquisition efficiency and minimizing time consumption of an entire module process.

In some embodiments, the process of performing a light-on test on the display panel 100 may include: acquiring the identification information of the display panel 100; downloading the simulation diagram from the target position based on the identification information; and controlling the display panel 100 to display the simulation diagram, so as to perform the light-on test. For example, the light-on test station may collect the identification information of the display panel 100 through the identification collection device, so that the host computer may acquire the identification information of the display panel 100 arriving at the station in real time, thereby acquiring the simulation diagram adapted to the display panel 100 from the target position based on the identification information. It should be noted that the host computer that uploads the simulation diagram and the host computer that downloads the simulation diagram may be the same host computer or different host computers, which is specifically set based on needs of actual application scenario, and the present disclosure is not limited thereto.

In some embodiments, after the host computer downloads the simulation diagram from the target position, the simulation diagram may be stored in a local designated storage path, and then the simulation diagram is called from the designated storage path and loaded into a programmer in real time, so as to be displayed on the display panel 100. In some embodiments, downloading the simulation diagram from the target position may start immediately after the identification information of the display panel 100 (e.g., scanning code) is collected, and the simulation diagram may be displayed while being downloaded, so as to reduce time consumption of a light-on test process, thereby ensuring that the upload and download of data substantially do not affect the time consumption of the entire module process.

After executing the step S140, that is, the assembly of the second PCB 120 is completed, the step S150 may be executed to download and burn the brightness compensation data. It should be noted that the host computer that uploads the brightness compensation data and the host computer that downloads the brightness compensation data may be the same host computer or different host computers, which is set based on needs of actual application scenario, and the present disclosure is not limited thereto. In some embodiments, a host computer of an assembly station for the second PCB 120 may acquire the identification information of the display panel 100, the brightness compensation data may be downloaded from the target position based on the identification information of the display panel 100, and the downloaded brightness compensation data may be burned into the first memory chip 122 provided on the second PCB 120.

For example, the assembly station for the second PCB 120 may collect the identification information of the display panel 100 arriving at the station through the identification collection device and send the identification information to the host computer, so that the host computer may acquire the brightness compensation data adapted to the display panel 100 from the target position based on the acquired identification information.

In some embodiments, in order to ensure reliability of data burning, before burning the brightness compensation data, to-be-burned brightness compensation data may be verified, if verification of the brightness compensation data is successful, the brightness compensation data is burned into the first memory chip 122. In some embodiments, the first PCB 110 is provided with the second memory chip 114 used to store verification data.

Based on this, as shown in FIG. 7, after generating the brightness compensation data in the above-mentioned step S120, the method of manufacturing the display module 10 provided by some embodiments of the present disclosure further includes: generating verification data of the brightness compensation data, and writing the verification data into the second memory chip 114. For example, the brightness compensation data is a binary file, and the verification data may be a cyclic redundancy check (CRC) code or other applicable verification codes.

When the host computer uploads the brightness compensation data, the verification data of the brightness compensation data also needs to be uploaded. As shown in FIG. 7, the process of storing the brightness compensation data and the identification information of the display panel 100 in association in the target position in the above-mentioned step S120 includes: storing the brightness compensation data, the verification data of the brightness compensation data, and the identification information of the display panel 100 in association in the target position.

Accordingly, as shown in FIG. 7, in the above-mentioned step S150, the brightness compensation data and the verification data of the brightness compensation data may be downloaded from the target position based on the identification information of the display panel 100. The verification data may be read from the second memory chip 114. The read verification data is compared with the downloaded verification data, and in a case that the read verification data is consistent with the downloaded verification data, the downloaded brightness compensation data may be burned into the first memory chip 122 provided on the second PCB 120. It should be noted that in a case that the read verification data is inconsistent with the downloaded verification data, it is indicated that there is an error in the data. The error needs to be checked and resolved in time before burning correct brightness compensation data into the first memory chip 122, thereby ensuring that the wrong data is not burned into the screen.

In some embodiments, the brightness compensation data, the verification data of the brightness compensation data, the simulation diagram, and the identification information of the display panel 100 are stored in association in the target position. In some embodiments, in order to ensure reliability of the simulation diagram used for the light-on test, when the light-on test is performed on the display panel 100, the downloaded simulation diagram may be verified using the verification data, if verification is successful, the display panel 100 is controlled to display the downloaded simulation diagram, so as to test a lighting effect.

The above-mentioned process of downloading the simulation diagram from the target position based on the identification information of the display panel 100, and controlling the display panel 100 to display the simulation diagram includes: downloading the simulation diagram and the verification data from the target position based on the identification information of the display panel 100; reading the verification data from the second memory chip 114; and comparing the read verification data with the downloaded verification data, and in a case that the read verification data is consistent with the downloaded verification data, controlling the display panel 100 to display the simulation diagram. In a case that the read verification data is inconsistent with the downloaded verification data, it is indicated that there is an error in the data. The error needs to be checked and resolved in time before controlling the display panel 100 to display a correct simulation diagram, so as to ensure reliability of a light-on test result.

It should be noted that, in addition to the above-mentioned steps S110 to S150, the method of manufacturing the display module 10 may further include other process steps. For specific details, reference may be made to the related art, and no further description will be provided herein.

FIG. 8 shows a Demura effect diagram of an exemplary curved screen. Diagram (a) in FIG. 8 is a lighting effect diagram before CG bonding without Demura. Diagrams (b) and (c) in FIG. 8 are lighting effect diagrams after Demura according to the manufacturing method provided by some embodiments of the present disclosure, in which the diagram (b) is a lighting effect diagram before the CG bonding, and the diagram (c) is a lighting effect diagram after the CG bonding and plugging of the second PCB 120. It can be seen from FIG. 8 that a Mura phenomenon in the diagram (a) is obvious, while brightness in the diagrams (b) and (c) is uniform, which may meet brightness uniformity requirements. Therefore, performing the Demura process before the CG bonding may also effectively eliminate the Mura phenomenon of the display panel 100 without affecting a final product effect of the module.

Therefore, through the method of manufacturing the display module 10 provided by some embodiments of the present disclosure, the Demura process may be performed before the CG bonding without affecting the final product effect of the module. In addition, the time consumption of the entire module process may substantially not be affected, and a production efficiency may be high.

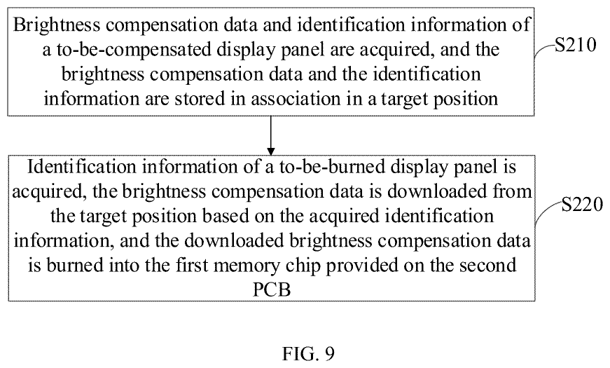

Some embodiments of the present disclosure further provide a brightness compensation method for the display module 10 provided in any one of the above-mentioned embodiments. In some embodiments, the brightness compensation method may be performed by a host computer. FIG. 9 shows a flowchart of a brightness compensation method according to some embodiments of the present disclosure. As shown in FIG. 9, the brightness compensation method may include at least the following steps S210 to S220.

In the step S210, brightness compensation data and identification information of a to-be-compensated display panel are acquired, and the brightness compensation data and the identification information are stored in association in a target position.

In the step S220, identification information of a to-be-burned display panel is acquired, the brightness compensation data is downloaded from the target position based on the acquired identification information, and the downloaded brightness compensation data is burned into the first memory chip provided on the second PCB board.

It should be noted that, for the specific implementation process of steps S210 and S220, reference may be made to the relevant descriptions in the above-mentioned embodiments, and they will not be repeated here. The steps S210 and S220 may be executed by the same host computer or different host computers, which may be determined based on needs of actual application scenarios, and the present disclosure is not limited thereto. For example, when the steps S210 and S220 are executed by different host computers, the step S210 may be executed by the host computer of the Demura station, and the step S220 may be executed by a host computer of the assembly station for the second PCB 120.

In some embodiments, the first PCB of the display module 10 is provided with the second memory chip. The above-mentioned process of storing the brightness compensation data and the identification information in association in the target position may include: generating verification data of the brightness compensation data; writing the verification data into the second memory chip 114; and storing the brightness compensation data, the verification data of the brightness compensation data, and the identification information in association in the target position. For the specific implementation process and effects, reference may be made to the relevant descriptions in the above-mentioned embodiments, and they will not be repeated here.

In some embodiments, the above-mentioned process of downloading the brightness compensation data from the target position based on the acquired identification information and burning the downloaded brightness compensation data into the first memory chip 122 provided on the second PCB 120 may include: downloading the brightness compensation data and the verification data of the brightness compensation data from the target position based on the acquired identification information; reading the verification data from the second memory chip 114; comparing the read verification data with the downloaded verification data, and in a case that the read verification data is consistent with the downloaded verification data, burning the downloaded brightness compensation data into the first memory chip 122 provided on the second PCB 120 of the display panel 100. For the specific implementation process and effects, reference may be made to the relevant descriptions in the above-mentioned embodiments, and they will not be repeated here.

In some embodiments, the above-mentioned process of storing the brightness compensation data, the verification data of the brightness compensation data, and the identification information in association in the target position includes: obtaining a simulation diagram for a light-on test based on the brightness compensation data; and storing the brightness compensation data, the simulation diagram and the identification information in association in the target position. For the specific implementation process and effects, reference may be made to the relevant descriptions in the above-mentioned embodiments, and they will not be repeated here.

In some embodiments, the above-mentioned brightness compensation method further includes: acquiring identification information of a to-be-tested display panel 100, downloading the simulation diagram from the target position based on the acquired identification information, and controlling the to-be-tested display panel 100 to display the downloaded simulation diagram, so as to perform the light-on test. It should be noted that, for the specific implementation process and effects of the step, reference may be made to the relevant descriptions in the above-mentioned embodiments, and they will not be repeated here. In addition, the step and the above-mentioned step S210 and/or step S220 may be executed by the same host computer or different host computers, which may be determined based on needs of actual application scenarios, and the present disclosure is not limited thereto. In some embodiments, the step may be executed by a host computer of the light-on test station.

In some embodiments, the above-mentioned process of downloading the simulation diagram from the target position based on the acquired identification information and controlling the display panel 100 to display the downloaded simulation diagram may include: downloading the simulation diagram and verification data from the target position based on the acquired identification information; reading the verification data from the second memory chip 114; comparing the read verification data with the downloaded verification data, and in a case that the read verification data is consistent with the downloaded verification data, controlling the to-be-tested display panel 100 to display the simulation diagram. For the specific implementation process and effects, reference may be made to the relevant descriptions in the above-mentioned embodiments, and they will not be repeated here.

Some embodiments of the present disclosure further provide an electronic device, including: a memory, a processor, and a computer program stored in the memory and executable on the processor, where the computer program, when executed by the processor, is used to implement the steps of the above-mentioned brightness compensation method. For the specific steps and effects of the brightness compensation method, reference may be made to the relevant descriptions in the above-mentioned method embodiments, and they will not be repeated here. The electronic device may be an electronic device with a host computer function and a communication function, such as a personal computer, which may achieve the upload and download of data. The electronic device provided by embodiments of the present disclosure is not limited to the types listed above.

Some embodiments of the present disclosure further provide a computer program product, and the computer program product, when executed by a processor, is used to implement the steps of the above-mentioned brightness compensation method, and the same technical effects may be achieved. For the sake of avoiding repetition, details will not be repeated here.

Some embodiments of the present disclosure further provide a computer-readable storage medium having a computer program stored thereon, and the computer program, when executed by a processor, is used to implement the steps of the above-mentioned brightness compensation method, and the same technical effects may be achieved. For the sake of avoiding repetition, details will not be repeated here. For example, the computer-readable storage medium may be a read-only memory (ROM), a random access memory (RAM), a magnetic disk, or an optical disk, etc.

It should be noted that the accompanying drawings of embodiments of the present disclosure only involve the structures related to embodiments of the present disclosure. For other structures, reference may be made to the general design. Without a conflict, the features in embodiments of the present disclosure may be combined with each other to form new embodiments.

Although some embodiments of the present disclosure have been described, those skilled in the art may make additional changes and modifications to these embodiments once they learn the basic creative concept. Therefore, the appended claims are intended to be interpreted as including the preferred embodiments and all changes and modifications falling within the scope of the present disclosure.

1. A display module, comprising:
a display panel;
a first printed circuit board PCB bound to the display panel, wherein the first PCB is provided with a transfer interface;
a second printed circuit board PCB provided with a timing control chip and a first memory chip, wherein the timing control chip is electrically connected to the first memory chip; and
a transfer circuit comprising a first connection terminal and a second connection terminal, wherein the first connection terminal is electrically connected to a signal output terminal of the second PCB, and the second connection terminal is plugged and connected to the transfer interface, so as to transmit a signal output by the second PCB to the first PCB.

2. The display module according to claim 1, wherein the first PCB is further provided with a second memory chip configured to store verification data, the verification data is used to verify to-be-burned brightness compensation data, if verification of the to-be-burned brightness compensation data is successful, the brightness compensation data is burned into the first memory chip.

3. The display module according to claim 1, wherein the second PCB is further provided with a power management integrated circuit, a level shift circuit and a gamma circuit, the power management integrated circuit and the level shift circuit are electrically connected to the timing control chip, and the gamma circuit is electrically connected to the power management integrated circuit.

4. A method of manufacturing the display module according to claim 1, the method comprising:
binding the display panel to the first PCB;
performing a Demura process on the display panel in advance to generate brightness compensation data for the display panel, and storing the brightness compensation data and identification information of the display panel in association in a target position;
forming a cover plate on the display panel;
plugging the second PCB into the first PCB; and
downloading the brightness compensation data from the target position based on the identification information of the display panel, and burning the downloaded brightness compensation data into the first memory chip provided on the second PCB.

5. The method according to claim 4, wherein the first PCB is provided with the second memory chip, and after generating the brightness compensation data for the display panel, the method further comprises:
generating verification data of the brightness compensation data, and writing the verification data into the second memory chip;
wherein the storing the brightness compensation data and identification information of the display panel in association in a target position comprises:
storing the brightness compensation data, the verification data of the brightness compensation data and the identification information of the display panel in association in the target position; and
wherein before burning the downloaded brightness compensation data into the first memory chip provided on the second PCB, the method further comprises:
reading the verification data from the second memory chip;
comparing the read verification data with the verification data of the downloaded brightness compensation data; and
in response to the read verification data being consistent with the verification data of the downloaded brightness compensation data, burning the downloaded brightness compensation data into the first memory chip provided on the second PCB.

6. The method according to claim 4, wherein after forming the cover plate on the display panel and before plugging the second PCB into the first PCB, the method further comprises: performing a light-on test on the display panel;
wherein before storing the brightness compensation data and the identification information of the display panel in association in the target position, the method further comprises: obtaining a simulation diagram for the light-on test based on the brightness compensation data; and
wherein the storing the brightness compensation data and identification information of the display panel in association in a target position comprises:
storing the brightness compensation data, the simulation diagram and the identification information of the display panel in association in the target position.

7. The method according to claim 6, wherein the performing a light-on test on the display panel comprises:
acquiring the identification information of the display panel;
downloading the simulation diagram from the target position based on the identification information; and
controlling the display panel to display the simulation diagram, so as to perform the light-on test.

8. The method according to claim 7, wherein the first PCB is provided with the second memory chip, and after generating the brightness compensation data for the display panel, the method further comprises:
generating verification data of the brightness compensation data, and writing the verification data into the second memory chip;
wherein the storing the brightness compensation data, the simulation diagram and the identification information of the display panel in association in the target position comprises:
storing the brightness compensation data, the verification data of the brightness compensation data, the simulation diagram and the identification information of the display panel in association in the target position; and
wherein the downloading the simulation diagram from the target position based on the identification information of the display panel, and controlling the display panel to display the simulation diagram comprises:
downloading the simulation diagram and the verification data from the target position based on the identification information of the display panel;
reading the verification data from the second memory chip;
comparing the read verification data with the downloaded verification data; and
in response to the read verification data being consistent with the downloaded verification data, controlling the display panel to display the simulation diagram.

9. A display apparatus, comprising the display module according to claim 1.

10. A brightness compensation method for the display module according to claim 1, comprising:
acquiring brightness compensation data for a to-be-compensated display panel and identification information of the to-be-compensated display panel, and storing the brightness compensation data and the identification information in association in a target position; and
acquiring identification information of a to-be-burned display panel, downloading the brightness compensation data from the target position based on the acquired identification information, and burning the downloaded brightness compensation data into the first memory chip provided on the second PCB.

11. The method according to claim 10, wherein the first PCB of the display module is provided with the second memory chip, and the storing the brightness compensation data and the identification information in association in a target position comprises:
generating verification data of the brightness compensation data;
writing the verification data into the second memory chip; and
storing the brightness compensation data, the verification data of the brightness compensation data and the identification information in association in the target position.

12. The method according to claim 11, wherein the downloading the brightness compensation data from the target position based on the acquired identification information, and burning the downloaded brightness compensation data into the first memory chip provided on the second PCB comprises:
downloading the brightness compensation data and the verification data of the brightness compensation data from the target position based on the acquired identification information;
reading the verification data from the second memory chip; and
comparing the read verification data with the downloaded verification data, and;
in response to the read verification data being consistent with the downloaded verification data, burning the downloaded brightness compensation data into the first memory chip provided on the second PCB.

13. The method according to claim 11, wherein the storing the brightness compensation data, the verification data of the brightness compensation data and the identification information in association in the target position comprises:
obtaining a simulation diagram for a light-on test based on the brightness compensation data; and
storing the brightness compensation data, the simulation diagram and the identification information in association in the target position.

14. The method according to claim 13, further comprising:
acquiring identification information of a to-be-tested display panel;
downloading the simulation diagram from the target position based on the acquired identification information, and controlling the to-be-tested display panel to display the downloaded simulation diagram, so as to perform the light-on test.

15. An electronic device, comprising: a memory, a processor, and a computer program stored in the memory and executable on the processor, wherein the computer program, when executed by the processor, is configured to implement steps of the brightness compensation method according to claim 10.
